(19) United States
(12) Patent Application Publication
(10) Pub. No.: US 2016/0111302 A1
(43) Pub. Date: Apr. 21, 2016

(54) Systems and Methods for Wet Processing Substrates with Rotating Splash Shield

(71) Applicant: Intermolecular, Inc., San Jose, CA (US)

(72) Inventors: Satbir Kahlon, Livermore, CA (US); Bernardo Donoso, San Jose, CA (US); Jeffrey Chih-Hou Lowe, Cupertino, CA (US); Robert Sculac, Lake Oswego, OR (US)

(21) Appl. No.: 14/519,363

(22) Filed: Oct. 21, 2014

(51) Int. Cl. H01L 21/67; B08B 3/02; B08B 3/04; B05B 15/04; B05B 3/02

(52) U.S. Cl. CPC H01L 21/67023; B05B 15/04; B05B 3/02; B08B 3/04; B08B 3/02

(57) ABSTRACT

Embodiments provided herein provide systems and methods for wet processing substrates with a rotating splash shield. The systems include a fluid dispenser configured to dispense a processing fluid. A substrate support configured to support and rotate a substrate is also included. The substrate support is disposed such that the processing fluid dispensed by the fluid dispenser flows onto the substrate. A splash shield is positioned on at least one side of the substrate support and is configured to rotate. The splash shield has an upper portion extending above an upper surface of the substrate and a lower portion extending below a lower surface of the substrate.

The present invention relates to wet processing techniques for substrates. More particularly, this invention relates to wet processing systems and methods utilizing a rotating splash shield.

### BACKGROUND

One type tool, or system, commonly used in the processing of substrates (e.g., semiconductor substrates) is spin rinse and dry (SRD) modules. SRD modules typically dispense processing fluids (e.g., cleaning solutions, rinsing solutions, deionized water, etc.) onto the substrate and remove the processing fluids and dry the substrate via spinning. A problem often associated these systems is the splashing of the processing fluids off various portions of the system, back onto the substrate, causing contamination of the substrate.

During the rotation of the substrate, there are two major forces acting on the processing liquid as it spun off the substrate: a centrifugal force and a tangential force. The centrifugal force pulls the liquid toward the edge of substrate, and the tangential force is at tangent angle to the edge of substrate. Both of these forces are dependent on the speed, or rate, of the rotation of the substrate. Generally, the higher the speed of rotation, the more likely it is that at least some of the liquid will splash back onto the substrate due to the increased kinetic energy of the liquid as it is spun off the substrate.

Additionally, some of the liquid may be splashed onto the ceiling of the module. Although the liquid on the ceiling may not initially be a problem, over time, the liquid may accumulate and/or deposit material on the ceiling. The liquid and/or material may eventually fall onto the substrate being process, which causes further contamination.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a simplified cross-sectional view of a wet processing system according to some embodiments.

FIG. 2 is top view of a chuck within the wet processing system of FIG. 1, according to some embodiments.

FIG. 3 is a top view of the chuck of FIG. 2 with a substrate positioned thereon.

FIG. 4 is a top view of a splash shield within the wet processing system of FIG. 1, according to some embodiments.

FIG. 5 is a cross-sectional view of the splash shield of FIG. 4 taken along line 5-5.

FIG. 6 is a top view of the chuck of FIG. 3 with the splash shield of FIG. 4 positioned on the chuck.

FIG. 7 is a side view of the chuck and splash shield of FIG. 6 taken along line 7-7.

FIG. 8 is a cross-sectional view of a portion of the splash shield of FIG. 4 when installed in the system of FIG. 1, along with a substrate within the system, according to some embodiments.

FIG. 9 is a simplified cross-sectional view of the system of FIG. 1 illustrating removal of a lid of the system, along with the splash shield of FIG. 4.

FIG. 10 is a cross-sectional view similar to that of FIG. 8, further illustrating removal of the lid of the system, along with the splash shield.

FIG. 11 side view similar to that of FIG. 7, illustrating the splash shield being removed from the chuck.

FIG. 12 is a flow chart illustrating a method for processing a substrate according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide substrate processing systems and methods related to, for example, dispensing processing fluids, such as cleaning and/or rinsing solutions, onto substrates and removing the fluids/drying the substrates via spinning (e.g., spin rinse and dry (SRD) systems).

In some embodiments, splashing and/or contamination caused by splashing may be reduced by utilizing a splash shield that rotates with the substrate. The use of a splash shield that rotates with the substrate may eliminate the tangential component of the force applied to the liquid as it is spun off the substrate. Thus, when the liquid hits the rotating splash shield, less splash back may occur because the liquid impacts the splash shield with less kinetic energy than would be the case of the splash shield was not rotating (i.e., because both the substrate and the splash shield are rotating at the same rotational speed, reducing the relative velocity to of the liquid to near zero).

The upper edge of the splash shield may extend above the upper surface of the substrate and have a profile that extends towards the center of the substrate. This portion of the splash shield may be at a small angle (e.g., 1-30 degrees) to the upper surface of the substrate to further reduce the likelihood that any liquid will splash back onto the substrate (e.g., because the liquid being spun off will contact this surface at a small angle, as opposed to 90 degrees). The bottom edge of the splash shield may extend below the bottom surface of the substrate to reduce the likelihood that any liquid flowing off the splash shield will contact the substrate. The bottom edge of the splash shield may have profiled surface that is at an angle of, for example, between 1 and 90 degrees to guide the liquid flow that is spinning off the splash shield.

In some embodiments, the splash shield rests on the substrate support (or chuck) in such a way that when the substrate support is rotated, the splash shield also rotates (e.g., the splash shield has grooves that mate with portions of the substrate support). In such embodiments, the splash shield may be simply lifted off the substrate support to remove it (e.g., to transport the substrate to/from the chamber). Further, the splash shield may have pins (or other members) that extend toward the walls of the chamber, or more particularly, the lid. In turn, the lid may have a corresponding structure (e.g., a ring) that may be used to lift the splash shield off the substrate support (e.g., when the lid is removed). However, it should be noted that in some embodiments, the splash shield may be permanently connected to (e.g., integral with) the substrate support.

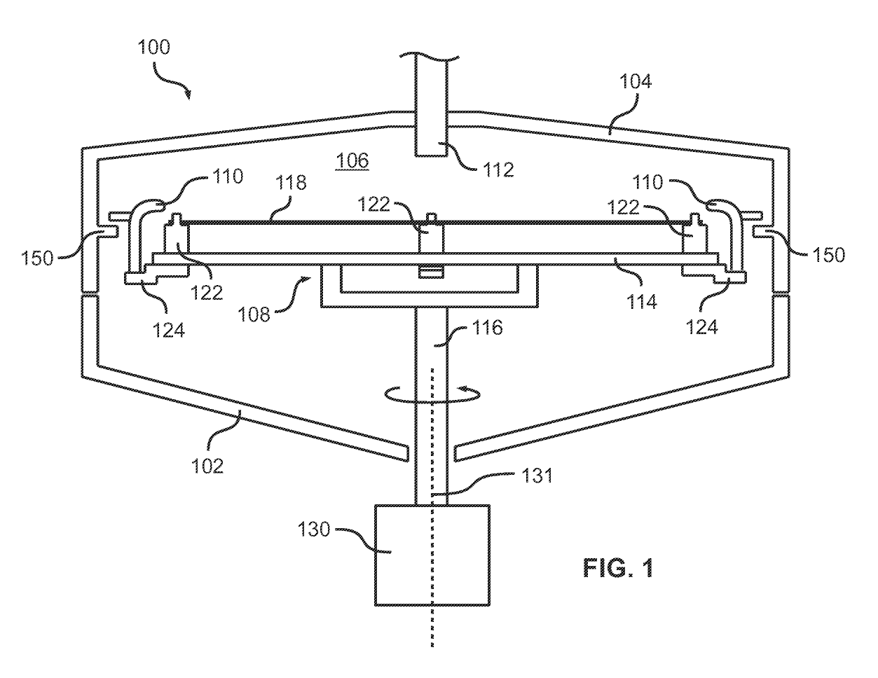

FIG. 1 illustrates a wet processing system (or tool) 100 according to some embodiments. The system 100 may be a spin rinse and dry (SRD) wet processing system, as is commonly understood. In the depicted embodiment, the system 100 includes a base (or lower portion) 102 and a lid (or an upper portion) 104 which jointly define (or enclose) a processing chamber 106. In some embodiments, the lid 104 is not permanently coupled to the base 102. More specifically, in some embodiments, the lid 104 rests on top of the base 102 and may be removed by exerting a force on the lid 102 in a direction away from the base 102 (i.e., by lifting the lid 102 off the base).

Although not specifically shown, in some embodiments the system 100 (and/or the base 102 and the lid 104) is substantially circular in shape (i.e., when viewed from the top or bottom). Also, in some embodiments, the base 102 includes one or more outlets for draining processing fluids.

Within the processing chamber 106, a substrate support (or substrate support assembly) 108, a splash shield 110, and a nozzle 112 are provided. In some embodiments, the substrate support 108 is configured to support a substrate 118 and includes a chuck 114 and a support shaft 116.

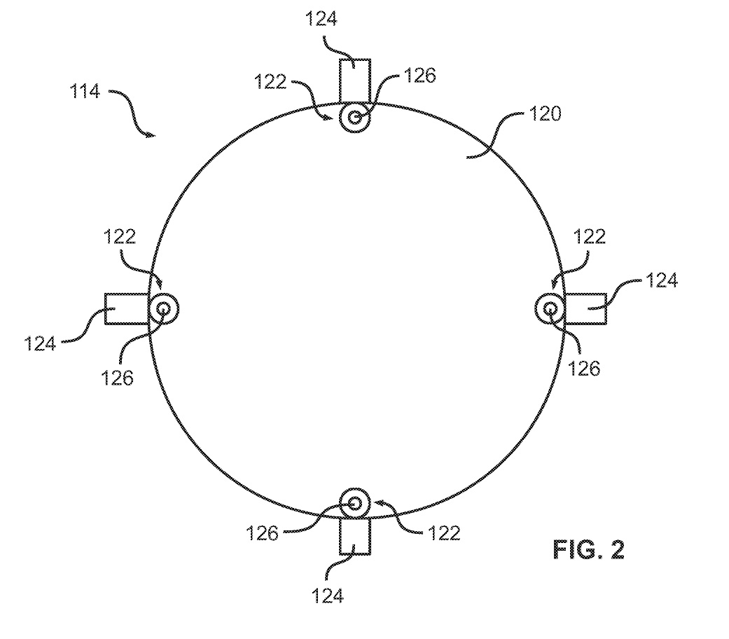

FIG. 2 is a top view of the chuck 114, without the substrate 118 position thereon, according to some embodiments. Referring to FIG. 2 in combination with FIG. 1, the chuck 114 includes a main body 120, substrate pins 122, and shield supports 124. In the depicted embodiment, the main body 120 is circular in shape. The main body 120 may have a width (or diameter) that is similar to, or slightly greater than, that of the substrate 118 (as described below). In some embodiments, the substrate pins 122 are connected to and extend upwards from the main body 120 along an outer portion thereof. The substrate pins 122 may be substantially cylindrical in shape. In some embodiments, each of the substrate pins 122 includes a tip 126 which has a width (or diameter) that is less than that of the remainder of the substrate pins 122. In the depicted embodiment, four substrate pins 122 are included, however, in other embodiments, a different number of substrate pins 122 may be used (e.g., three, five, or more).

Still referring to FIGS. 1 and 2, in some embodiments, the shield supports 124 are connected to the main body 120 of the chuck 114 and extend from the main body 120 on a side thereof opposite the substrate pins 122. As shown, the shield supports 124 laterally extend from a central portion of the main body 120 such that the outer portions thereof extend beyond the outer edge of the main body 120. In some embodiments, each of the shield supports 124 is associated with a respective one of the substrate pins 122 (i.e., for each shield support 124 there is one substrate pin 122). However, in some embodiments, the number of shield supports 124 may be different (i.e., more or less) than the number of substrate pins 122. The shield supports 124 and the substrate pins 122 may be formed from a single, integral piece of material and be connected to the main body 120 by inserting each of the substrate pins 122 through respective holes formed through the outer portion of the main body 120. In some embodiments, the portion(s) of the shield supports 124 that extends beyond the outer edge of the main body 120 are substantially rectangular in shape. However, in other embodiments, the shape of these portions of the shield supports 124 may be different, such as oval, semi-circular, etc.

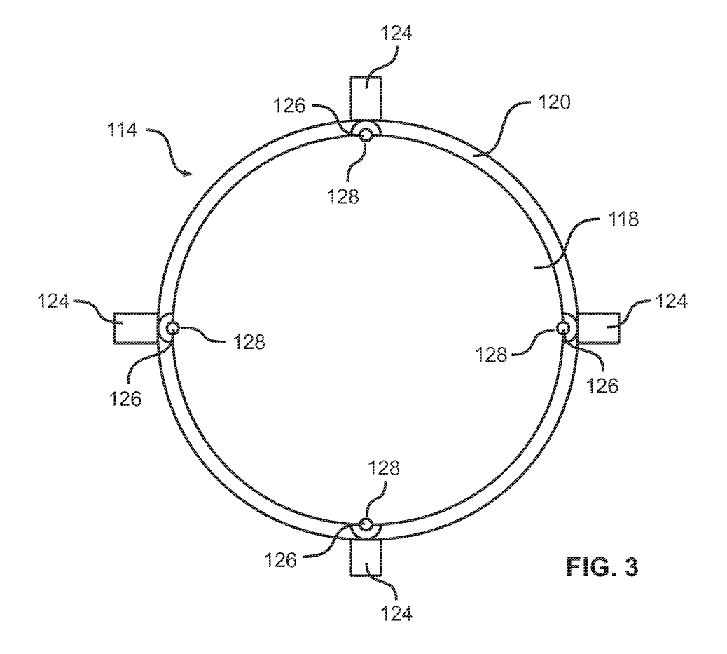

FIG. 3 is a top view of the chuck 114 with the substrate 118 positioned on the substrate pins 122 (FIG. 2). In some embodiments, the substrate is a substantially round wafer with a diameter of, for example, 200 millimeters (mm), 300 mm, 450 mm, or any other size. In some embodiments, substrate 118 may have a different shape (e.g., square, rectangular, etc). In some embodiments, the substrate 118 is made of a semiconductor material, such as silicon, gallium arsenide, and/or germanium. However, in some embodiments, substrate 118 may be made of other materials, such as glass, plastics, polymers, metals.

As is shown in FIG. 2, when the substrate 118 is positioned on (and supported by) the substrate pins 122, the substrate 118 is centered over the main body 120 of the chuck 114. In some embodiments, the substrate 118 includes a plurality of notches 128 formed in (or on) an outer edge thereof. Each of the notches 128 may correspond to one of the substrate pins 122 (FIG. 2) and/or the tips 126 thereof. That is, when the substrate 118 is placed on the substrate pins 122, the tip 126 of each of the substrate pins 122 may be positioned within one of the notches 128 on the substrate 122. As such, the substrate 118 is rotationally coupled to the chuck 114 via the mating of the tips 126 of the substrate pins 122 and the notches 128 on the substrate. As a result, when the chuck 114 is rotated, the substrate 118 also rotates.

Referring again to FIG. 1, an upper portion of the support shaft 116 of the substrate support 108 is coupled to the chuck 114, while a lower portion of the support shaft 116 extends through an opening in the base 102 of the system 100 and is coupled to a drive mechanism 130. Although not shown in detail, the drive mechanism 130 may include one or more actuators (e.g., electric motors, hydraulic pistons, etc.) configured to rotate the support shaft 116, and perhaps raise/lower the supports shaft 116 to adjust the distance between the chuck 114 (and/or the substrate 118) and the nozzle 112. In some embodiments, the support shaft 116 is coupled to the chuck 114 such that rotation of the support shaft 116 causes the chuck 114 to rotate about an axis 131. The axis 131 may extend through a central portion of the chuck 114 and/or the substrate 118. In some embodiments, the axis is congruent with a central axis of the chuck 114 and/or the substrate 118.

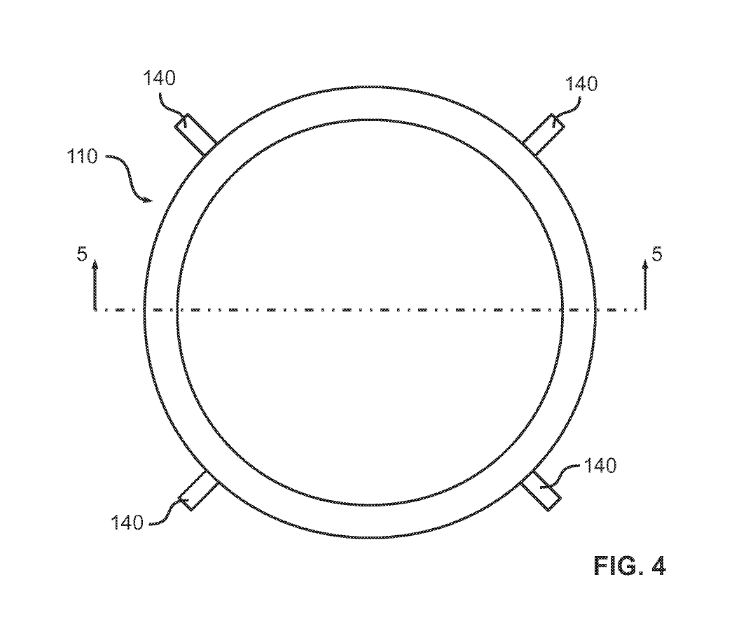

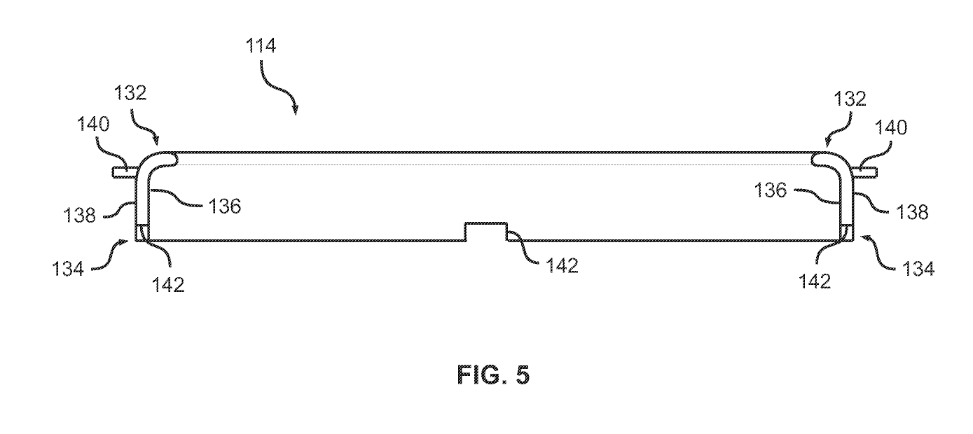

FIGS. 4 and 5 illustrate the splash shield 110 in greater detail. In some embodiments, the splash shield 110 is a substantially annular member made from a single, integral piece of material. The splash shield 114 has an upper portion (or end) 132, a lower portion (or end) 134, an inner surface 136, and an outer surface 138. As shown in FIG. 5, and will be explained in greater detail below, the splash shield 110 is shaped such that the upper portion 132 thereof curves (or extends) inwards towards a central portion (or opening) of the splash shield 110 such that the inner surface 136, at the upper portion 132, has a concave shape (and conversely, the outer surface 138, at the upper portion, has a convex shape).

As shown in FIGS. 4 and 5, the splash shield 110 also includes (one or more) lift tabs (or pins) 140 extending outwards from the outer surface 138, at the upper portion 132, thereof. In the depicted embodiment, the splash shield 110 has four lift tabs 140 that are evenly, or symmetrically, spaced around the periphery of the splash shield 110. However, it should be understood that in other embodiments, a different number (e.g., more or less) of lift tabs 140 may be used, and the lift tabs 140 may be spaced around the periphery of the splash shield 110 in an uneven, or asymmetric, manner. Furthermore, in some embodiments, a single, annular lift tab (or ring) may be used, which extends around the entire periphery of the splash shield 110.

Referring specifically to FIG. 5, in some embodiments, the splash shield further has a plurality of detents (or grooves) 142 formed in the lower portion 134 (more specifically, the lower edge) thereof. In some embodiments, the number of detents 142 is the same as the number of shield supports 124 on the chuck 114 of the substrate support 108. The detents 142 may also be arranged, or spaced, about the lower portion 134 of the splash shield 110 in a manner similar to how the shield supports 124 are arranged/spaced about the chuck 114.

In some embodiments, the chuck 114 and the splash shield 110 are made of a plastic or polymer, such as polytetrafluoroethylene (PTFE). However, other chemically inert materials, such as ceramics and some metals, may be used depending on the processing liquids utilized.

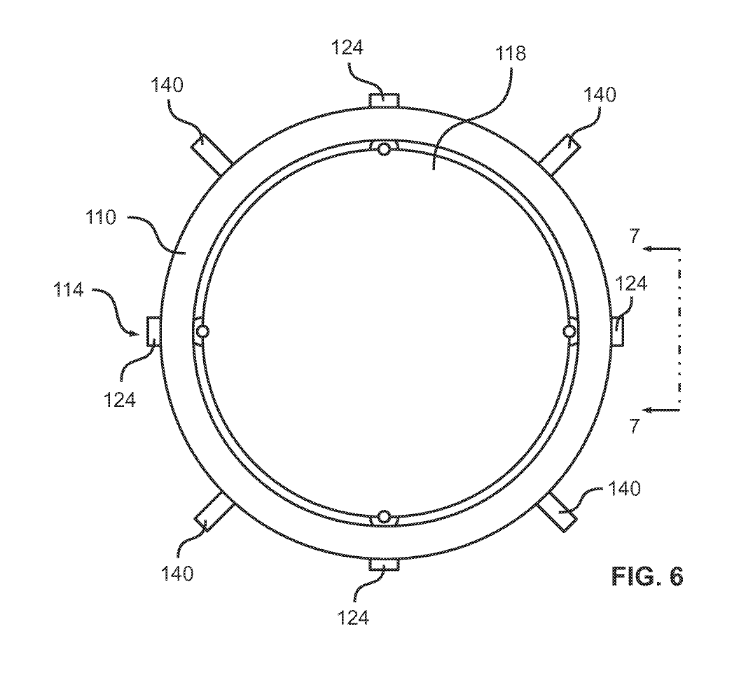

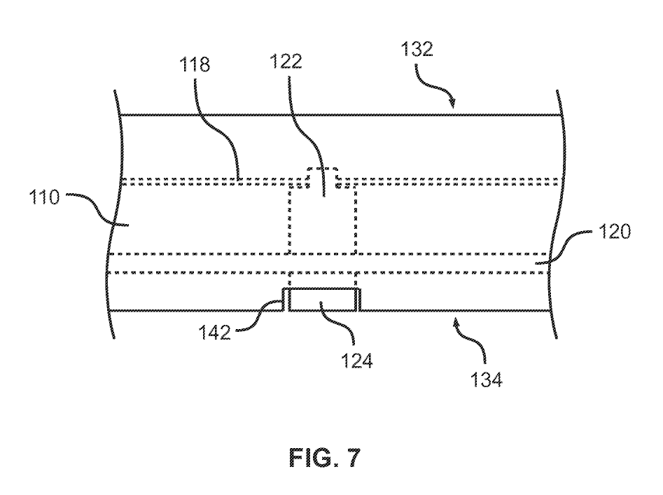

As shown in FIG. 1 in combination with FIGS. 6 and 7, in some embodiments, the splash shield 110 is placed onto the chuck 114 such that the splash shield 110 is centered on the chuck 114 and extends around a periphery of both the chuck 114 and the substrate 118. However, it should be noted that in some embodiments, the splash shield 110 may not completely circumscribe the periphery of the chuck 114 and/or the substrate 118 (e.g., the splash shield may only be positioned on/at selected portions around the chuck 114 and/or the substrate 118).

As shown in FIGS. 6 and 7, each of the shield supports 124 of the chuck 114 is inserted into one of the detents 142 in the lower portion 134 of the splash shield 110. In other words, each of the detents 142 on the splash shield 110 is aligned with a respective one of the shield supports 124 on the chuck 114. In some embodiments, the width of the shield supports 124 and the width of the detents 142 are substantially identical so that little, or no, rotational movement between the splash shield 110 and the chuck 114 is possible (i.e., when the splash shield 110 is installed/positioned as shown in the figures). As such, in some embodiments, when the chuck 114 is rotated, the splash shield 110 also rotates (e.g., about the same axis as the chuck 114 and/or the substrate 118), and when the chuck 114 stops rotating, the splash shield 110 also stops rotating.

FIGS. 1, 7, and 8 illustrate the position of the splash shield 110 relative to the substrate 118, as well as the lid 104 of the system 100, when the splash shield 110 and substrate 118 are installed/positioned on the chuck 114 as described above. It should be noted that the chuck 114 is not shown in FIG. 7 for purposes of clarity.

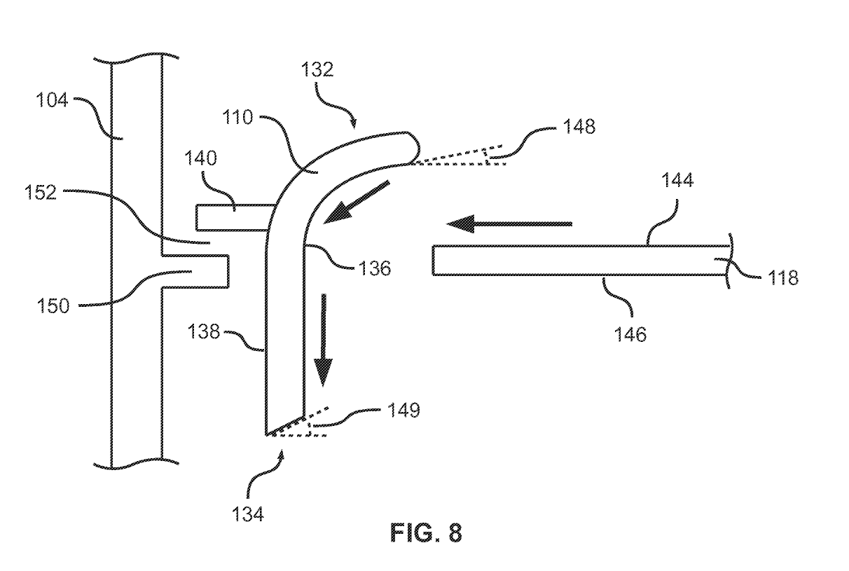

As most clearly shown in FIG. 8, when the splash shield 110 is installed, the upper portion 132 (and/or the upper end) of the splash shield 110 extends above (i.e., to a height greater than) an upper surface 144 of the substrate 118, while the lower portion 134 (and/or the lower end) of the splash shield extends below (i.e., to a height less than) a lower surface 146 of the substrate 118. In other words, both the upper surface 144 and the lower surface 146 of the substrate 118 are at a height between the height of the upper end of the splash shield 110 and the height of the lower end of the splash shield 110.

In some embodiments, the splash shield 110 is shaped such that the inner surface 136 of the splash shield 110 at the upper portion 132 (and/or end) thereof is at an angle 148 to the upper surface 144 of the substrate 118. In other words, as the upper portion 132 of the splash shield 110 extends towards the central portion of the substrate 118, the height of the inner surface 136 of the splash shield 110 above the upper surface 144 of the substrate 118 increases. In some embodiments, the angle 148 is between about 1 degree and about 30 degrees, preferably between about 5 degrees and about 15 degrees. In some embodiments, the upper portion 132 of the splash shield 110 does not extend to a position directly above the substrate 118 (i.e., there is a gap between the lateral position of the upper end of the splash shield 110 and the outer edge of the substrate 118).

In some embodiments, the lower end 134 of the splash shield 110 is profiled as shown such that the bottom surface thereof is at an angle 149 to the upper surface 144 of the substrate 118. In some embodiments, the angle 149 is between about 1 degree and about 90 degrees, such as between about 20 degrees and about 60 degrees.

Referring to now to FIGS. 1 and 8, the lid 104 of the system 104 further includes a lift member 150 extending inwards, towards the splash shield 110 from the sidewalls thereof. In some embodiments, the lift member 150 is a continuous, ring-shaped protrusion extending from the sidewalls of the lid 104. However, in some embodiments, multiple, distinct lift members are provided, which may be spaced around the inner surface of the lid. As most clearly shown in FIG. 8, when the splash shield 110 is positioned on the chuck 114 as described above and the lid 104 of the system 100 is fully seated on the base 102, the lift member 150 extends at least partially below the lift tabs 140 on the splash shield 110 such that a gap 152 is formed between the lift member 150 and the lift tab 140 (or in embodiments with multiple lift members 150 and multiple lift tabs 140, a gap 152 is formed between each lift member 150 and each lift tab 140). Thus, as is shown in FIG. 8, the splash shield 110 does not contact the lid 104 (or the base 102).

Referring again to FIG. 1, in some embodiments, the nozzle (or fluid dispenser) 112 extends though a top portion of the lid 104 of the system. The nozzle may be configured and arranged to dispense one or more processing fluids onto the substrate 118. More specifically, in some embodiments, the nozzle is arranged such that processing fluids dispensed therefrom flow onto the central portion of the substrate 118.

Although not specifically shown, the nozzle 112 may be in fluid communication with one or more processing fluid sources configured to provide processing fluids, such as liquids (e.g., cleaning solutions, rinsing solutions, deionized water, etc.), to the nozzle 112. Further, the system 100 may include a control sub-system (or controller) having, for example, a processor and a memory, which is in operable communication with the other components shown in FIG. 1 and configured to control the operation thereof in order to perform the methods described herein.

With the substrate placed on the chuck 114 and the splash shield 110 positioned on the shield supports 124, a processing liquid may be dispensed from the nozzle 112 onto the substrate 118. After at least some of the processing liquid is dispensed onto the substrate 118, the chuck 114, and thus the substrate 118, may be rotated by the drive mechanism 130 (e.g., about the axis 131). In some embodiments, the rotation of the chuck 114 causes rotation of the splash shield 110 (e.g., about the axis 131).

The rotation of the chuck 114, and the splash shield 110, may occur while the processing liquid is being dispensed. In some embodiments, the rotation of the chuck 114 and/or the substrate 118 continues after the cessation of the dispensing of the processing liquid. That is, the rotation of the chuck 114/substrate 118 may continue for some time, such as between about 10 seconds and about 5 minutes, after the dispensing of the processing liquid has been ceased. In some embodiments, the substrate 118 is rotated at any rate between 0 revolutions per minute (rpm) and about 2500 rpm, such as about 1200 rpm, for any duration (e.g., between about 5 seconds and about 5 minutes).

Thus, in some embodiments, rotation of the splash shield 110 is caused by the rotation of the chuck 114, which is driven by the drive mechanism 130. However, in other embodiments, a separate actuator may be provided for the splash shield 110 so that the splash shield 110 may be rotated in a manner independent of (e.g., in a different direction and/or at a different speed/rate than) the chuck 114 and/or the substrate 118.

Referring specifically to FIG. 8, as the substrate 118 is rotated, a centrifugal force causes the processing liquid to be “spun” outwards, off the upper surface 144 of the substrate 118, and into the splash shield 118 (i.e., the inner surface 136 of the splash shield 110). Because the mating between the splash shield 110 and the chuck 114, the splash shield 110 is rotated with the substrate 118 (and the chuck 114). Thus, the centrifugal force may essentially be the only force acting on the processing liquid as the processing liquid impacts the inner surface 136 of the splash shield 110. In other words, because the splash shield 110 is rotating with the substrate 118, there may be substantially no tangential component to the force with which the processing liquid impacts the splash shield 110. As a result, the odds of any of the processing liquid splashing off the splash shield 110 and back onto the substrate 118 are reduced, thus minimizing any potential contamination of the substrate 118.

Additionally, due to the size and shape of the splash shield 110, particularly the profile of the inner surface 136 of the splash shield 110, the odds of any splash back/contamination are further reduced. Specifically, because the upper portion 132 of the splash shield 110 extends inwards, towards the center portion of the substrate 118, and/or the angle 148 between the inner surface 136 of the splash shield 110 at the upper portion 132 of the splash shield 110 and the upper surface 144 of the substrate 110, processing liquid that impacts the inner surface 136 of the splash shield 110 at the upper portion 132 thereof is gradually deflected by and flows down the inner surface 136, as opposed to splashing off the splash shield 110 (i.e., and perhaps back onto the substrate 118). Such a flow of the processing liquid is indicated by the arrows in FIG. 8.

This effect may be enhanced by minimizing the lateral spacing between the inner surface 136 of the splash shield 110 and the substrate 118. That is, in some embodiments, the lateral spacing between the splash shield 110 and the substrate 118 combined with the rate at which the substrate 118 is rotated is such that the processing liquid impacts the splash shield 110 before the stream of flow of the processing liquid off the upper surface 144 of the substrate 118 is broken (i.e., a substantially constant stream of processing liquid flows off the substrate 118 into the splash shield 110, as opposed to the processing liquid breaking apart into individual portions/drops).

Additionally, shape, profile, and position of the splash shield, particularly the inner surface 136 on the upper portion 132, may prevent any of the processing from splashing upwards onto the ceiling of the processing chamber 106 (i.e., the top portion of the lid 104), which may otherwise lead to additional contamination. Furthermore, because the lower portion 134 (or end) of the splash shield 110 is at a height below that of the lower surface 146 of the substrate 110, processing liquid flowing off the lower portion 134 of the splash shield 110 is unlikely to impact the lower surface 146 of the substrate 118. The angle 149 at the bottom end 134 of the splash shield 110 may further assist in guiding the liquid flowing off the splash shield 110 away from the lower surface 146 of the substrate 118.

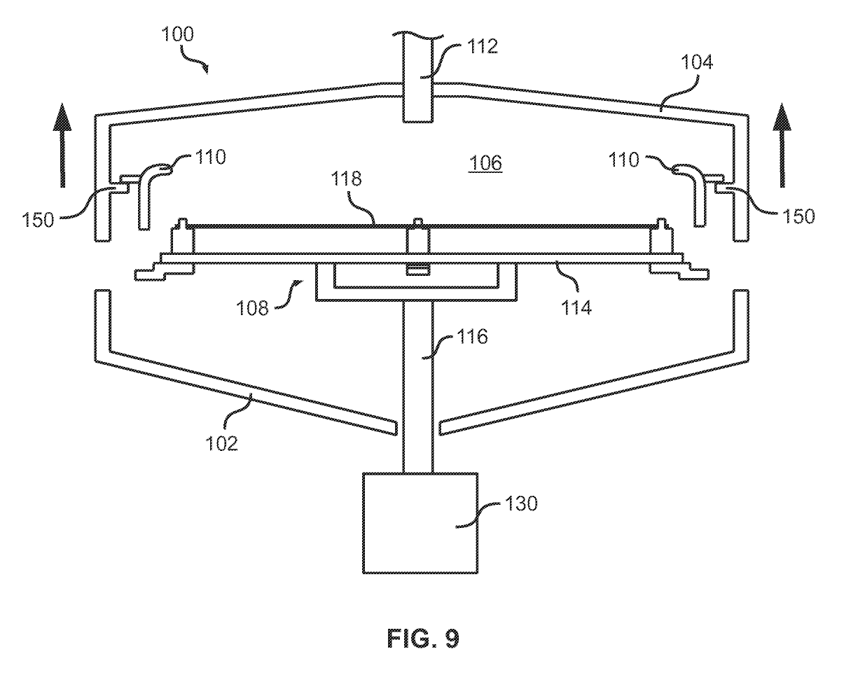

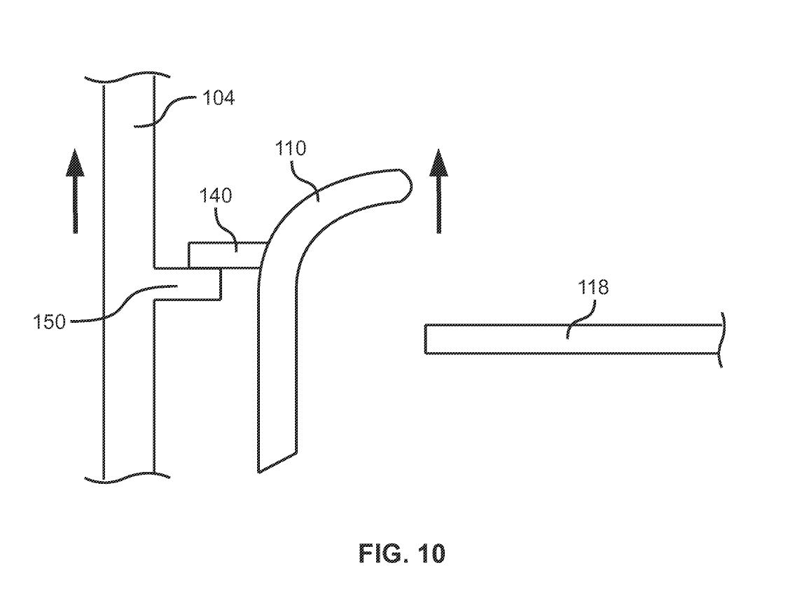

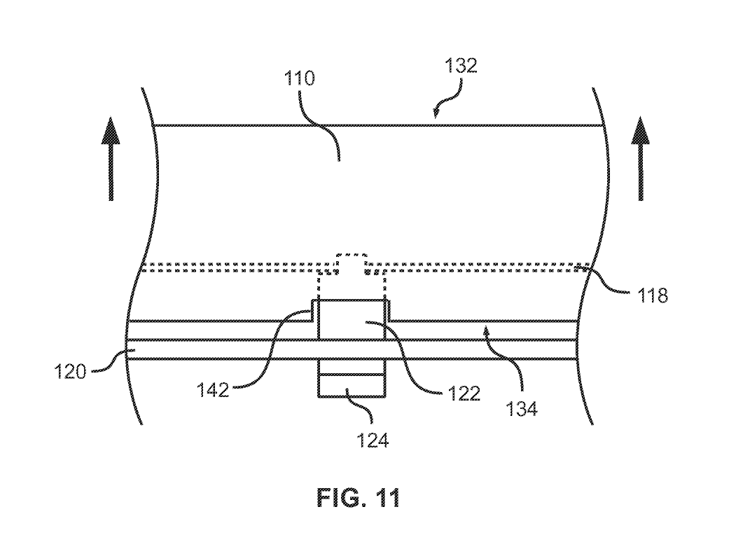

Referring now to FIGS. 9, 10, and 11, after the processing of the substrate 118 is completed (i.e., the dispensing of the processing liquid and the rotation of the substrate 118 have ceased), the lid 104 of the system 100 may be lifted off the base 102 to provide access to the processing chamber 106 and allow the substrate 118 to be removed from the substrate support 108. As is shown in FIGS. 9-11, as the lid 104 is lifted off the base 102, the lift member 150 on the lid 104 contacts the lift tabs 140 on splash shield 110, thereby exerting a force on the splash shield 110 in a direct towards the nozzle 112 and/or away from the chuck 11 such that the splash shield 110 is lifted off of (or decoupled from) the chuck 114, and thus also removed from the system 100.

After the lid 104 and the splash shield 110 are removed, the substrate 118 may be lifted off the chuck 114 and replaced by a subsequent substrate to be processed in a manner similar that described above. When the lid 104 is placed back onto the base 102, the splash shield 110 may also be positioned back onto, and aligned with, the chuck 114 in the manner described above.

However, it should be noted that in some embodiments, the splash shield 110 may be permanently connected to the chuck 114 such that it can not be lifted off the chuck 114. For example, the splash shield 110 may be formed as an integral piece of the chuck 114 (e.g., the splash shield and the chuck 114 may be made from a single piece of material). In such embodiments, the splash shield 110 may be appropriately sized and shaped so that the substrate 118 may be placed onto and removed from the chuck 114 through the opening in the splash shield 110.

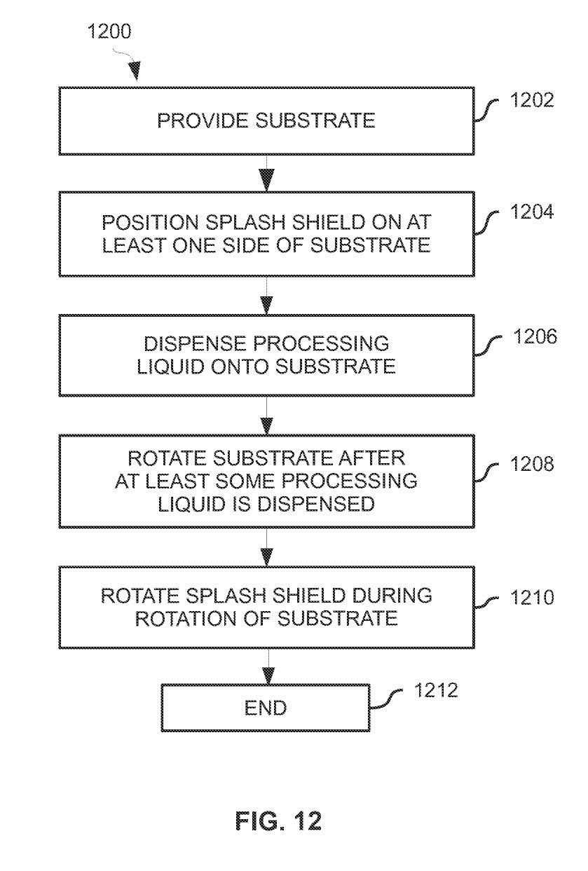

FIG. 12 illustrates a method 1200 for processing a substrate according to some embodiments. At block 1202, a substrate is provided. In some embodiments, the substrate is a substantially round wafer with a diameter of, for example, 200 millimeters (mm), 300 mm, 450 mm, or any other size. In some embodiments, substrate may have a different shape (e.g., square, rectangular, etc). The substrate may be made of a semiconductor material, such as silicon, gallium arsenide, and/or germanium. However, in some embodiments, substrate may be made of different materials, such as glass, plastics, polymers, metals, etc.

At block 1204, a splash shield is positioned at least one side of the substrate. In some embodiments, the splash shield extends around a periphery of the substrate. The splash shield may have an upper portion that extends to a height greater than (i.e., above) an upper surface of the substrate and a lower portion that extends to a height less than (i.e., below) a lower surface of the substrate. The splash shield may be shaped such that the upper portion thereof extends towards a central portion of the substrate. In some embodiments, an inner surface of the splash shield at the upper portion thereof is at an angle to the upper surface of the substrate. The angle may be between about 5 degrees and about 30 degrees (e.g., between about 5 degrees and about 15 degrees).

In some embodiments, the splash shield is supported by a substrate support on which the substrate is placed. The splash shield may mate with the substrate support such that when the substrate support (and/or the substrate) is rotated, the splash shield also rotates. In some embodiments, the splash shield may be lifted off of the substrate support.

At block 1206, a processing liquid (e.g., a cleaning or rinsing solution) is dispensed onto the substrate (e.g., the upper surface of the substrate). At block 1208, the substrate is rotated after at least some of the processing liquid is dispensed onto the substrate. The rotation of the substrate may occur while the processing liquid is being dispensed onto the substrate. In some embodiments, the rotation of the substrate continues after the cessation of the dispensing of the processing liquid. In some embodiments, the substrate is rotated at between about 0 rpm and about 2500 rpm, such as about 1200 rpm. In some embodiments, the substrate is rotated about a central portion (e.g., axis) thereof.

At block 1210, the splash shield is rotated while the substrate is rotated. In some embodiments, the splash shield is rotated in the same direction and at the same rate as the substrate. The rotation of the splash shield may (also) occur while the processing liquid is being dispensed onto the substrate.

Thus, in some embodiments, substrate processing systems are provided. The processing systems include a fluid dispenser configured to dispense a processing fluid. A substrate support configured to support and rotate a substrate is also included. The substrate support is disposed such that the processing fluid dispensed by the fluid dispenser flows onto the substrate. A splash shield is positioned on at least one side of the substrate support and configured to rotate with the substrate. The splash shield has an upper portion extending above an upper surface of the substrate and a lower portion extending below a lower surface of the substrate.

In some embodiments, substrate processing systems are provided. The processing systems include a fluid dispenser configured to dispense a processing fluid. A substrate support configured to support and rotate a substrate about an axis is also included. The substrate support is disposed below the fluid dispenser such that the processing fluid dispensed by the fluid dispenser flows onto the substrate. A splash shield is arranged about a periphery of the substrate. The splash shield has an upper portion extending above an upper surface of the substrate and a lower portion extending below a lower surface of the substrate. The splash shield is coupled to the substrate support such that the rotation of the substrate about the axis causes rotation of the splash shield about the axis and causes the processing fluid dispensed onto the substrate to flow towards the splash shield.

In some embodiments, methods for processing a substrate are provided. A substrate having an upper surface and a lower surface is provided. A splash shield is positioned on at least one side of the substrate. The splash shield has an upper portion extending above the upper surface of the substrate and a lower portion extending below the lower surface of the substrate. A processing liquid is dispended onto the upper surface of the substrate. The substrate is rotated after at least some of the processing liquid is dispensed onto the upper surface of the substrate. During the rotating of the substrate, the splash shield is rotated.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A substrate processing system comprising:
a fluid dispenser configured to dispense a processing fluid;
a substrate support configured to support and rotate a substrate, the substrate support being disposed such that the processing fluid dispensed by the fluid dispenser flows onto the substrate; and
a splash shield on at least one side of the substrate support and configured to rotate with the substrate, wherein the splash shield has an upper portion extending above an upper surface of the substrate and a lower portion extending below a lower surface of the substrate.

2. The substrate processing system of claim 1, wherein the splash shield extends around a periphery of the substrate support.

3. The substrate processing system of claim 2, wherein the upper portion of the splash shield extends towards a central portion of the substrate support.

4. The substrate processing system of claim 3, wherein the splash shield comprises an inner surface and an outer surface.

5. The substrate processing system of claim 4, wherein at least a portion of the inner surface of the splash shield at the upper portion thereof is at an angle to the upper surface of the substrate.

6. The substrate processing system of claim 5, wherein the upper portion of the splash shield is shaped such that a vertical distance between the at least a portion of the inner surface of the splash shield at the upper portion thereof increases as the upper portion of the splash shield extends towards the central portion of the substrate.

7. The substrate processing system of claim 6, wherein the angle is between about 5 degrees and about 30 degrees.

8. The substrate processing system of claim 4, wherein the splash shield is sized and positioned such that the inner surface of the splash shield is spaced apart from the substrate.

9. The substrate processing system of claim 8, wherein the splash shield is coupled to the substrate support such that the rotation of the substrate causes the rotation of the splash shield.

10. The substrate processing system of claim 9, wherein the splash shield is coupled to the substrate support such that a force exerted on the splash shield in a direction towards the fluid dispenser causes the splash shield to be decoupled from substrate support.

11. A substrate processing system comprising:
a fluid dispenser configured to dispense a processing fluid;
a substrate support configured to support and rotate a substrate about an axis, the substrate support being disposed below the fluid dispenser such that the processing fluid dispensed by the fluid dispenser flows onto the substrate; and
a splash shield arranged about a periphery of the substrate, the splash shield having an upper portion extending above an upper surface of the substrate and a lower portion extending below a lower surface of the substrate,
wherein the splash shield is coupled to the substrate support such that the rotation of the substrate about the axis causes rotation of the splash shield about the axis.

12. The substrate processing system of claim 11, wherein the splash shield has an inner surface on a side thereof adjacent to the substrate and an outer surface on a side thereof opposite the substrate, and wherein the splash shield is shaped such that the inner surface at the upper portion thereof extends towards the axis.

13. The substrate processing system of claim 12, wherein at least a portion of the inner surface of the splash shield at the upper portion thereof is at an angle of between about 5 degrees and about 30 degrees to the upper surface of the substrate.

14. The substrate processing system of claim 11, wherein the splash shield is coupled to the substrate support such that a force exerted on the splash shield in a direction towards the fluid dispenser causes the splash shield to be lifted from substrate support.

15. The substrate processing system of claim 12, wherein the splash shield is sized and positioned such that the inner surface of the splash shield is spaced apart from the substrate.

16. A method for processing a substrate, the method comprising:
providing a substrate having an upper surface and a lower surface;
positioning a splash shield on at least one side of the substrate, wherein the splash shield has an upper portion extending above the upper surface of the substrate and a lower portion extending below the lower surface of the substrate;
dispensing a processing liquid onto the upper surface of the substrate;
rotating the substrate after at least some of the processing liquid is dispensed onto the upper surface of the substrate; and
during the rotating of the substrate, rotating the splash shield.

17. The method of claim 1, wherein the splash shield extends around a periphery of the substrate.

18. The method of claim 16, wherein the splash shield is rotated in the same direction and at the same rate as the substrate.

19. The method of claim 18, wherein the upper portion of the splash shield extends towards a central portion of the substrate.

20. The method of claim 19, wherein the splash shield comprises an inner surface and an outer surface, and wherein at least a portion of the inner surface of the splash shield at the upper portion thereof is at an angle to the upper surface of the substrate, the angle being between about 5 degrees and about 30 degrees.
